(19) United States
(12) Patent Application Publication
(10) Pub. No.: US 2020/0187350 A1
(43) Pub. Date: Jun. 11, 2020

(54) PAPER-IN-RESIN ELECTRONICS - PROCESS FOR PRODUCING IT AND APPLICATION IN MANUFACTURED PRODUCTS

(71) Applicant: ARJO WIGGINS FINE PAPERS LIMITED, MANCHESTER (GB)

(72) Inventors: Gaël DEPRES, CHIRENS (FR); Jean-Marie VAU, PARIS (FR)

(21) Appl. No.: 16/614,464

(22) PCT Filed: May 16, 2018
(86) PCT No.: PCT/EP2018/062820

§ 371 Date: Nov. 18, 2019

(30) Foreign Application Priority Data
May 16, 2017 (EP) 17305560.9

(51) Int. Cl. H05K 1/03; H05K 1/09; D21H 19/36; H05K 3/12; B32B 29/00

(52) U.S. Cl. CPC H05K 1/0386; H05K 1/092; D21H 19/36; H05K 3/1216; H05K 3/125; B32B 2250/26; H05K 3/1275; H05K 3/1283; B32B 29/005; H05K 2201/0284; B32B 2255/12; H05K 3/1266

(57) ABSTRACT

The invention relates to a paper-based printed electronic device comprising one or more sheets of paper that is impregnated with a resin in way to fill the voids (or pores) of porous networks of cellulose fibers and in particular to saturate said porous networks of cellulose fibers, as well as to coat the outer surfaces of the printed electronics with said resin. A fully encapsulated electronic device is obtained which is protected against external environmental and physical damages such as against moisture and oxygen and has acquired sufficient resistance to tearing. The impregnated and encapsulated electronic device can then be successfully integrated into an object in a form of a flat or curved monolithic structure. This may especially be achieved through a lamination process, as said device sustains high pressure, high temperature, does not create bubbles, does not delaminate, and can be fully embedded into an end product.

### BACKGROUND OF THE INVENTION

The invention relates to “Paper in Resin electronics” and accordingly provides a paper-based printed electronic device impregnated and encapsulated with a resin, which is in a form of a monolithic structure, in particular a flat or curved monolithic structure. The monolithic structure (in particular flat or curved) may in particular be obtained by carrying out a lamination process. As such, the paper-based printed electronic device (hereafter referred to as the electronic device for convenience) may then be integrated or embedded into a product or an object, for example, by performing a lamination process while providing at the same time the monolithic structure.

Accordingly, the invention relates to the preparation of electronic devices that may be involved in Internet-of-Things wherein the electronic device would be embedded in different materials (paper, wood, glass, plastics . . . ).

Printed electronics enable electrically functional inks to be printed on a range of flexible substrates to form circuitries that can fulfill many different functions in applications such as smart objects, displays, communication devices, RFID tags, sensors, energy harvesting devices, to name a few.

Among various flexible substrates, paper serves as an attractive alternative to plastic film due to its thermal stability and recyclability. Patent applications WO 2013/104520 and WO2015/059157 disclose paper substrates suitable for printing functional inks for printed electronics, which exhibit suitable smoothness, high thermal stability, and ink absorption characteristics that allow less quantity of inks to be applied on said paper substrates to achieve desired electrical properties, such as electrical conductivity.

Nevertheless, paper substrates are prone to tearing and hygroscopic in nature (i.e. cellulose fibers absorb moisture from the surrounding environment), which limit their use in wider applications. In fact, most electronic devices require an excellent barrier against environmental factors such as moisture, oxygen, and physical damages, which are contributors to degradation, reduced lifetime, or failure. Especially, paper-based electronics in the applications of ultra-high frequency (UHF), Wi-Fi, Bluetooth Low Energy (BLE) or even higher frequency antenna confront difficulties due to considerable dielectric losses at high frequency (above 1 GHz). Thus, there exists a need for an effective protection of paper based electronics against moisture, oxygen, and physical damages.

Encapsulation of electronic devices by lamination with plastic films is known. Similarly, electronic devices can be embedded in injection-moulded plastics. It has been also shown that electronic devices are first laminated with plastic films and then incorporated in an In-Mould Process.

However, the use of plastic films to encapsulate electronic devices and/or embedding electronic devices in injection-moulded plastics have several important drawbacks that selected papers do not exhibit.
In high temperature sintering, plastic films show noticeable drop in their physical characteristics. A temperature range of 120° C. to 140° C. is the maximum processing temperature range for polyethylene terephthalate (PET) and polyethylene naphthalate (PEN), whereas paper can withstand temperatures up to 200° C. to 220° C. without significant decrease in mechanical properties. Sintering is usually required for obtaining functional electronic circuits from substrates printed with electronic ink, in particular with inks comprising metallic particles. Lower temperature sintering, due to temperature constraints of the substrate, induces the need for higher amount of expensive electronic inks, in order to reach the desired electronic properties.
Due to their higher temperature sensitivity compared to paper, plastic films show a poor thermal dimensional stability. This drawback causes registration issues during the printing steps.
Plastic films are more difficult to print by basic techniques than paper. Their runnability on printing machines is difficult due to static electricity, leading to lower speed operation. The ability of the ink to dry on plastic film is much lower than on paper, due to the lack of porosity of films. This also impacts negatively the operation speeds. The adhesion of inks and therefore the resistance to set off, scratch and rub are lower on plastic films, due to the lack of porosity and the lower surface energy.

Plastic films show significant restrictions on adhesion to polymers of other chemical nature. As examples, polyester (in particular polyethylene terephthalate, PET), which is commonly used in the flexible printed electronic industry, has a poor affinity with polyamide (PA) and polyolefins (polypropylene, polyethylene). Polyolefins have a poor affinity with most of the common polymers used in the plastic industry. This limitation would mean that in most cases, it would be necessary to use as the base substrate for the label a film made of the same polymer as the one used for the final plastic piece. To overcome this critical drawback when producing the product, it is necessary to insert an adhesion medium between the two surfaces. This can be done either by coinjection, coextrusion, hot melt bonding, adhesion primer coating or any other means known by the expert. But these technical operations can be complex, are time consuming, lead to production waste and finally significantly increase the overall process cost. Moreover, polymers tend to have different thermal expansion coefficients, which lead to lack of adhesion or even separation of polymer complex or sandwich on cooling after production of the plastic piece.

Paper has been used as a laminate for décor applications for many years. Thanks to the porous networks of cellulose fibers and their affinity to resins, one or more sheets of papers are accordingly saturated with a resin and glued together under heat and pressure to form a monolithic structure. The laminated paper product is robust, rigid, resistant to scratches, dirt, and water, and can be decorated. Applications of paper laminate include flooring, decorative interior, exterior panels, roofing, etc.

The present application aims to leverage some of the unique features of paper, in particular its porosity and its affinity to resins, to open up new application fields including the production of electronic devices and products comprising such devices embedded or integrated therein.

### SUMMARY OF THE INVENTION

The invention relates to a paper-based printed electronic device comprising one or more sheets of paper that is impregnated with a resin in way to fill the voids (or pores) of porous networks of cellulose fibers and in particular to saturate said porous networks of cellulose fibers, as well as to coat the outer surfaces of the printed electronics with said resin. A fully encapsulated electronic device is obtained which is protected against external environmental and physical damages such as moisture and oxygen and has acquired sufficient resistance to tearing. The impregnated and encapsulated electronic device can then be successfully integrated into an object in a form of a flat or curved monolithic structure. This may especially be achieved through a lamination process, as said device sustains high pressure and high temperature, does not create bubbles, does not delaminate, and can be fully embedded into an end product.

It has been observed by the inventors that contrary to the results obtained with laminates using plastics as substrate for the electronic device, using paper sheets as functional sheets in the electronic device does not provide fragility to the laminated product when such device is integrated into said laminated product which is finally obtained after the lamination process. In particular, with such laminated paper sheets used as substrate for the electronic device no delamination of the laminate has been observed and the strength of the produced laminate is similar to that of plastic-based laminates.

It has been also observed that the impregnated resin remains stable and does not damage the circuitry comprising both a printed ink portion and other rigid electronic components such as silicon components, in particular silicon chips. Furthermore, by replacing the water trapped within papers with a resin, drawbacks related to the water content in the paper are overcome. Importantly, the laminated electronic device employing a paper sheet having a defined Bendtsen porosity according to the invention exhibits excellent oxygen and moisture barrier properties.

The invention also relates to a process or method for producing an electronic device comprising the steps of:

(i) providing or producing a plurality of sheets, at least one of said sheets is a paper comprising a printed trace, pattern, and/or layer of electronic ink;

(ii) optionally impregnating and encapsulating one or more sheets provided or produced in step (i) with a resin;

(iii) assembling said plurality of sheets in a direction perpendicular to the plane of the sheets;

(iv) when step (ii) was not carried out, impregnating and encapsulating the plurality of sheets with a resin;

(v) optionally laminating the plurality of resin impregnated and encapsulated sheets and

(vi) recovering a flat or curved monolithic structure.

In a particular embodiment, the sheets, in particular the paper sheet(s) used in the preparation of the monolithic structure of the device encompassing an electronic device comprising a plurality of assembled sheets all have a Bendtsen porosity greater than 1 ml/min, preferably in the range of 1 to 200 ml/min, more preferably a low porosity in the range of 1 to 50 ml/min, while more preferably in the range of 1 to 10 ml/min, and still more preferably in the range of 1 to 5 ml/min when measured according to the Bendtsen method. Bendtsen porosity of a paper represents the air permeance of the paper and describes the flow of air passing through the paper. The inventors have observed that the porosity of the paper significantly influences the impregnation of the structure by the resin and enables obtaining a monolithic structure after the cross-linking of the resin. Porosity in this range of values is in particular obtained with Powercoat® XD paper (Arjowiggins).

In particular, the sheet(s) comprising printed traces, layers or patterns of electronic ink(s) has(have) a Bendtsen porosity greater than 1 ml/min, preferably in the range of 1 to 200 ml/min, more preferably a low porosity in the range of 1 to 50 ml/min, and a smoothness, especially a Bekk smoothness greater than 50 s, preferably greater than 80 s.

According to a further embodiment and in particular in combination with the above embodiment, the paper sheet(s) comprising a printed trace, pattern, and/or layer of an electronic ink(s) has(have) Bendtsen porosity in the range of 1-200 ml/min and a Bekk smoothness greater than 50 s, preferably greater than 80 s, and below 2000 s, preferably below 900 s.

According to a further embodiment and in particular in combination with the above embodiment, the paper sheet(s) comprising a printed trace, pattern, and/or layer of an electronic ink(s) has(have) Bendtsen porosity in the range of 1-50 ml/min and a Bekk smoothness greater than 50 s, preferably greater than 80 s, and below 2000 s, preferably below 900 s.

### DETAILED DESCRIPTION OF THE INVENTION

Provided herein is an electronic device comprising a plurality of sheets assembled in a direction perpendicular to the plane of the sheets (z-direction), wherein at least one of said sheets is a sheet of paper comprising a printed trace, pattern, and/or layer of an electronic ink, and wherein the assembly of plurality of sheets is impregnated and encapsulated with a resin in a form of a flat or curved monolithic structure.

The terms “trace”, “pattern”, and “layer” are used herein as nouns with their usual meanings in the field of printed electronics, i.e. “trace” designates any visible deposition of a printed ink, “pattern” designates any continuous or consistent arrangement of a printed ink, and “layer” designates a printed portion of an ink covering a wider or the entire surface area of a sheet.

Accordingly “trace”, “pattern”, and “layer” elements are electronic components which are, individually or when connected to each other and/or to further components, functional electronic components. Said functionality is maintained after the printed and assembled device is impregnated and encapsulated with the resin. The trace(s), pattern(s), or layer(s) of an electronic ink, unless otherwise indicated, are fully cured or sintered at optimal conditions according to the specification of the ink used and therefore, does not contain any solvent. Preferably, the curing or sintering of an electronic ink, in particular a conductive ink comprising metal particles, is carried out at a sufficiently high temperature, such as a temperature of at least 150° C. in particular at least 180° C., for the solvent contained in the ink to be removed, for example, by evaporation.

An “electronic ink” refers in the context of the present invention to inks conventionally used in the field of printed electronics, and is readily identifiable by a skilled person. In particular, an electronic ink has suitable electric and/or electronic properties, in particular conductance, resistance, and/or impedance properties and/or dielectric, semiconducting, photovoltaic and/or electroluminescent properties. Electronic inks comprise organic and inorganic inks. Organic inks comprise conductive polymers, polymer semiconductors, in particular conjugated polymers. Inorganic inks comprise in particular dispersions of metallic or semiconducting particles, in particular micro and nanoparticles, in particular silver and/or gold particles and/or particles comprising silicon or oxide semiconductors. Examples of such inks will be described in the following sections.

In a particular embodiment, at least two sheets of the plurality of the sheets are paper substrates comprising printed traces, patterns, and/or layers of an electronic ink.

In a particular embodiment the at least one paper sheet comprises printed one or more traces, patterns, and/or layers of a conductive ink.

In a further embodiment, at least one paper sheet comprises printed one or more traces, patterns, and/or layers of a semiconductive ink or a dielectric ink.

In another embodiment, at least one paper sheet comprises one or more types of electronic ink, in particular of conductive inks, semiconductive inks, and/or dielectric inks.

As disclosed herein, the term “conductive ink” encompasses materials possessing electrically conductive properties having a viscosity suitable to be printed by a printing method known to a skilled person. In particular, a conductive ink may comprise electrically conductive materials diluted or suspended in a solvent, which evaporates or solidifies upon curing or annealing so that the electrically conductive materials come in contact to allow electrical conductivity. The electrically conductive materials include inorganic and organic materials. Inorganic materials comprise metal particles, in particular microparticles or nanoparticles, in particular silver, copper and/or gold particles. Organic materials comprise conductive polymers. In a particular embodiment, the electrically conductive materials are microparticles or nanoparticles of silver, carbon, carbon nanotubes, silver chloride, or polyaniline (PAni).

The term “semiconductive ink” encompasses materials possessing electrically semiconductive properties having a viscosity suitable to be printed by a printing method known to a skilled person. In particular, a semiconductive ink may comprise semiconducting materials diluted or suspended in a solvent, which evaporate or solidifies upon curing or annealing so that the semiconducting materials come in contact to exhibit semiconducting properties. The semiconducting materials include inorganic and organic materials. Inorganic materials comprise semiconducting particles, in particular microparticles or nanoparticles, in particular particles comprising silicon or oxide semiconductors. Organic materials comprise polymer semiconductors, in particular conjugated polymers. In a particular embodiment, the semiconducting material includes poly-3-alkylthiophene (P3AT), and/or polyvinyledenedifluoride-tetrafluoroethylene (PVDF-TrFE).

The term “dielectric ink” encompasses materials possessing electrically non-conductive, insulating, or very poorly conductive properties having a viscosity suitable to be printed by a printing method known to a skilled person. In particular, a dielectric ink may comprise dielectric materials diluted or suspended in a solvent, which evaporate or solidifies upon curing or annealing. The dielectric materials include inorganic and organic materials. In a particular embodiment, dielectric material is polyhydroxystyrene (PHS).

In a particular embodiment, a printed paper sheet comprises one or more traces, patterns, and/or layers of one or more electronic inks, in particular one or more conductive inks, and/or one or more semiconductive inks, and/or one or more dielectric inks overlapping in various arrangements. For example, any one of conductive ink, semiconductive ink, and/or dielectric ink can be printed on a paper sheet. After curing (or sintering) the printed ink, any one of said inks can be printed on top of the previously printed and cured ink. This over-printing process can be repeated at least once and provides overlapping arrangements.

In a preferred embodiment, the paper sheet on which one or more traces, patterns and/or layers of an electronic ink is printed is resistant to a temperature up to 150° C., preferably at least up to 180° C., and even more preferably at least up to 200° C., and does not deform or distort dimensionally after curing or sintering of an electronic ink, in particular over multiple cycles.

In a particular embodiment, the plurality of sheets comprising printed traces, patterns, and/or layers of electronic inks, in particular conductive inks, and/or semiconductive inks, and/or dielectric inks are aligned perpendicularly to the plane of the sheets in a way to ensure electrical continuity and/or to form a functional electronic device.

Any of the thus defined embodiments of the electronic device may further include one or more additional electronic components which are printed or not-printed, i.e., are not produced as ink trace, pattern or layer and are functionally related to the printed electronic components.

In a particular embodiment, one or more discrete rigid electronic components are appended, in particular soldered or glued, to at least one sheet of the plurality of sheets, for example using pick and place. In particular embodiments, such non-printed components include a silicon based chip, in particular a chip forming part of an RFID transponder, and/or a diode, such as an LED, a resistor, a capacitor, an inductor, a transistor, a switch, a piezoelectric device, an antenna, a battery, a transducer, a logic gate, and/or a wire, such as a copper wire. In particular embodiments, the printed electronic circuit comprises essentially all the wiring of the circuit.

In a particular embodiment, at least one sheet comprises at least one electronic component, such as a resistor, a capacitor, a diode, an inductor, a transistor, an integrated circuit (IC), a switch, a piezoelectric device, an antenna, a battery, a transducer, a logic gate, or a sensor. In a particular embodiment, at least one sheet comprises a printed electrode or is an electrode. In a particular embodiment, said electronic components are printed with electronic ink, in particular conductive, semiconductive, and/or dielectric inks. In a further embodiment, the electronic components comprise non-printed rigid components.

In a preferred embodiment, the electronic components are connected together to create an electronic circuitry, for example by printing with one or more conductive inks and/or by wiring.

It has been surprisingly observed that the inclusion of rigid electronic components does not add any significant thickness to the monolithic structure and the lamination process does not damage said electronic components or the electronic circuit. Therefore, there is no need to compensate for the thickness of the rigid electronic components added within the assembly of the multiple sheets for the preparation of the monolithic structure.

In a particular embodiment, the electronic components of the electronic device are all provided on at least one, in particular more than one sheet of paper.

In a preferred embodiment, each sheet in the plurality of sheets comprised in the electronic device is a sheet of paper.

In a particular embodiment, the electronic device, after printing and before being impregnated and encapsulated with a resin is made of paper sheets only and comprises more than 2, in particular up to 100 and especially from 1 or from 2 to 100, from 1 or from 2 to 50 or from 10 to 100 or from 10 to 50 sheets of paper. In a particular embodiment, the electronic device comprises 1, 2, 3, 4, 5, 6, 7, 8, 9 or 10 sheets of paper, especially of paper with electronic components.

In a particular embodiment, all sheets, in particular paper sheets, of the plurality of sheets comprised in the preparation of the electronic device have a Bendtsen porosity greater than 1 ml/min, preferably in the range of 1 to 200 ml/min, more preferably in the range of 1 to 50 ml/min, while more preferably in the range of 1 to 10 ml/min, and still more preferably in the range of 1 to 5 ml/min. In one embodiment, a paper sheet having a Bendtsen porosity in the range of 1 to 200 ml/min is used as a substrate for applying an electronic ink by screen printing. In another embodiment, a paper sheet having a Bendtsen porosity in the range of 1 to 10 ml/min is used as a substrate for applying an electronic ink by ink-jet printing.

The Bendtsen porosity in said range is suitable for impregnation of the paper with a resin. When all sheets have a Bendtsen porosity in said range. All the sheets do not necessarily have the same Bendtsen porosity in the monolithic structure.

Advantageously, the surface of a paper sheet (to be) printed with an electronic ink has high smoothness. In a particular embodiment, said paper surface has a Bekk smoothness greater than 50 s, preferably greater than 80 s, and below 2000 s, preferably below 900 s.

In a particular embodiment, a paper sheet used as a substrate for printing trace(s), pattern(s) and/or layer(s) of an electronic ink has a Bendtsen porosity in the range of 1 to 200 ml/min, preferably in the range of 1 to 50 ml/min, more preferably in the range of 1 to 10 ml/min, and still more preferably in the range of 1 to 5 ml/min and a Bekk smoothness greater than 50 s, preferably greater than 80 s, and below 2000 s, preferably below 900 s.

In a preferred embodiment at least one paper sheet having the trace, pattern and/or layer of electronic ink(s) has a Bendtsen porosity within the range of 1 to 50 ml/min while having a Bekk smoothness greater than 80 s and less than 2000 s or less than 900 s.

The paper sheets of the electronic device may all be of the same type or alternatively may encompass different types of papers. In particular, the paper sheets intended for the printing or deposit of the electronic components may be of specific type(s) (such as disclosed hereafter) whereas additional sheets such as support sheets may be of a different type. As an example, Kraft paper may be used as a support sheet to receive the paper sheets comprising the electronic components. A decor paper sheet or a paper sheet rendered transparent or translucent may form the top sheet of the device. In a particular embodiment, the electronic device comprises one or more sheets of materials other than paper having suitable porosity, such as glass fiber and carbon fiber.

In a particular embodiment, the electronic device comprises multiple sheets of paper wherein at least one sheet of paper is Kraft paper intended as a support or bottom sheet, and a decor paper or a paper rendered transparent or translucent as a top sheet of the device, and one or more than one sheets of a coated paper receiving the electronic components; in particular the electronic component(s), in particular those which are printed with suitable ink, are printed on a coated paper selected for its ability as a support for said specific printing and for its ability to impregnation and encapsulation by resin after the printing step has taken place.

The paper intended for printing is thus selected for its properties to fulfill requirements related to temperature resistance, bulk porosity, surface smoothness, printing ability with the specific inks (functional inks) disclosed herein.

It is indicated that an advantage of the invention is to provide an electronic device wherein the various sheets that it encompasses do not need to be glued or bonded to their respective contiguous sheet(s) by an adhesive layer.

Papers suitable for electronics printing have been disclosed in the art and in particular in patent applications published as WO 2013/104520 and WO 2015/059157. Such papers as disclosed in WO 2013/104520 are characterized as very smooth papers with a roughness Ra in the range 1 to 30 nm, for example, which means that an electronically functional (e.g. conductive, semiconductive or dielectric) sheet can be produced by printing a layer of ink which is very thin. Alternatively, in order to enable inks that may be cheaper or in order to enable deposit of thicker layers of ink it may not be necessary to use a support with a side intended for printing that has to be as smooth as above stated. Accordingly, WO 2015/059157 discloses a paper comprising a surface with a roughness Ra which is, for example, in the range 0.1 to 3 μm and could be sufficient to produce high quality electroconductive sheets. The two types of papers having different smoothness also have different microporosity which may influence the adhesion of the ink to the surface and which may impact their impregnation by the resin.

Papers suitable for carrying out the present invention such as those described in the above patent applications and having the above disclosed features are papers which can act as a support for a trace, pattern or layer of conductive, semiconductive or dielectric ink deposited or in particular printed, and which is thermally resistant (low deformation or low dimensional shrinkage at high temperature, low yellowing effect) and as a consequence can be used to produce conductive tracks with good conductivity (in particular due to the relatively low porosity and/or low roughness of the surface of the paper which is to be printed). Such papers have also revealed suitable for resin impregnation according to the present invention after for deposition or printing of electronics components to enable production of a functional electronic device.

In particular embodiments, the paper substrate which harbours the electronic components is a coated paper substrate, wherein such coating is suitable for printing with electronic inks (conductive, semiconductive or dielectric ink) and in particular wherein such coating comprises pigments and a binder or a mixture of binders. Papers disclosed in WO 2013/104520 and WO 2015/059157 are coated papers suitable for printing with conductive, semiconductive or dielectric ink. They may be used in combination to produce the electronic device especially when some electronic components are better suited for printing or deposit on a very smooth or to the contrary on a less smooth paper (such as electrodes).

In particular embodiments of any of the above embodiments, the paper substrate comprises at 70 to 90% of short cellulosic fibers by dry weight. In particular embodiments, the coating comprises a binder with a glass transition temperature lower than 20° C., or event lower than 10° C. preferably and said coating comprises 5 to 50 parts by dry weight of such binder. In particular embodiments, the paper substrate has an ISO brightness and/or a D65 brightness in the range 70 to 90, preferably 75 to 85 and/or the difference in ISO brightness and/or D65 brightness before and after exposing the paper substrate to heat during 5 min at 180° C. is equal to or less than 3.

In a particular embodiment, the paper substrate may be of the type obtained using the process described in WO 2013/104520 to the extent that smoothness suitable to carry out the present invention may be achieved.

In a particular embodiment paper as disclosed in WO 2015/059157, is used such as Powercoat® XD. When producing said paper, the binder or binders layer deposited onto the surface of the paper and intended to be printed has(have) a low glass transition temperature, in particular 20° C. or less, preferably 10° C. or less, and the paper has thermal resistance that can be considerably improved, in particular in terms of deformation and said layer comprises 10 to 30 parts dry weight of binder with a glass transition temperature of 20° C. or less, preferably 15 to 25 parts dry weight, more preferably 19 parts dry weight. Preferably, an acrylic binder is used. In a particular embodiment of such paper, said layer may comprise 0.05 to 15 parts dry weight of viscosifying agent, more preferably 0.05 to 5 parts dry weight, and still more preferably 0.05 to 4 parts dry weight of such an agent. In particular, said layer may comprise 5 to 10 parts dry weight of polyvinyl alcohol used as a viscosifying agent, more preferably 8 parts dry weight.

The binder used to prepare the coating of the coated paper suitable for use according to the invention may be selected from acrylic polymer, polyurethane, polymethyl methacrylate, styrene butadiene, vinyl acetate, polyamide, nitrocellulose or any other cellulose, polyvinyl alcohol, starch and a mixture thereof.

In particular embodiments of any of the above embodiments, the paper substrate for printing electronic inks is a Powercoat® XD paper (Powercoat is a trademark of Arjowiggins).

In a particular embodiment of the invention, no glue or adhesive is used to assemble the sheets and in particular between the sheets harbouring electronic components for the preparation of the electronic device The invention accordingly concerns the use of coated papers such as Powercoat® XD paper in the preparation of an electronic device. In a particular embodiment of the invention, Powercoat® XD is particularly suitable for printing electronic inks, curing or sintering said inks, in particular at a high temperature above 150° C. or 180° C., and impregnating with a resin.

In a particular embodiment, the paper(s) comprised in the assembly of the plurality of sheets, in particular Powercoat® XD paper, may be rendered transparent or translucent after impregnation with a resin having a reflective index similar to that of the cellulose of said paper(s).

The resin with which the electronic device is impregnated and encapsulated may be selected among resins including urea formaldehydes (UF), melamine formaldehyde (MF), urea-melamine-formaldehyde (UMF), acrylic, phenolic, polyester, epoxy resins or mixtures thereof.

Also, the resin may be a thermoset resin, and in particular it may be selected among polyurethane, melamine, epoxy, polyesters, rubber and the like polyolefines, acrylic-acid ester polymers (homopolymers or copolymers), vinylpolymers, polyamides, polyesters, polyacetals and polycarbonates.

According to an embodiment, the resin may comprise further components or molecules, such as inorganic and/or organic components, in the form of chemicals, fillers, or solvents.

Once impregnated, the resin replaces water molecules within the pores of paper, and depending on the type of chemicals, fillers or solvents contained in the resin, the properties of paper may be modified. These properties include fire resistance, thermal conductivity for heatsinking, magnetic shielding, or even electrical conductivity between two sheets or layers of said papers.

The choice of the resin may depend upon the porosity of the paper to accept the proper amount of resin. During the impregnation step the resin penetrates into the pores of the paper including advantageously by migrating from one side to the other side of the paper. When the conditions for impregnation (in particular, the quantity of resin provided is adapted) and the porosity of the paper allows it, the resin may saturate the paper thereby displacing essentially all air from the pores of the paper. In a further step encapsulation of the device with the resin is achieved as a coating of all faces of the device with resin. When impregnation and encapsulation treatment has been performed, the device is dried and is then ready for lamination.

The resin is provided in a liquid state or as a dry “film”. During the impregnation process, the viscosity of the resin becomes low enough to penetrate into the pores of paper.

Impregnation and encapsulation are carried out in accordance with methods known from the person skilled in the art (i.e. where paper or other types of sheets are pre-impregnated) in order to achieve an electronic device which is protected from moisture and oxygen and where necessary from grease. Accordingly the sheets of the assembled device are coated, either individually before their assembly or after they have been assembled, with a resin in conditions enabling the pores of the sheets to be filled with the resin and all the surfaces of the sheet(s) to be coated. The impregnation may enable saturation of the pores of the sheets, or at least saturation of the pores of the most external sheets of the electronic devices, at least of a number of sheets sufficient to enable the moisture and oxygen barrier to be formed for the assembled electronic device. The coating of the top, bottom and lateral surfaces of the electronic device with the resin also provides the barrier sought and is carried out in a way that avoids surface defects.

According to an embodiment, at least one sheet of the plurality of sheets is provided as a pre-impregnated sheet with a resin for the assembly of the sheets in the device.

Impregnation and encapsulation may be carried out using rollers: the assembled sheets of the electronic device are accordingly provided on a pre-wetting roller which is partly in contact with a bath containing the liquid resin. The resin is provided on the roller as a film and is transferred to the side of the bottom side of the paper in conditions enabling resin to penetrate into the pores of the paper and when the paper circulated over further rollers the resin is allowed to migrate toward the other side of the paper. Where necessary, the paper may further be immersed in a bath of resin to ensure the coating of the top surface (where electronic components are printed/appended or bare) of the paper. The process is performed in such a way that the air and the water contained in the paper are displaced by the resin until advantageously saturation of the pores of the paper. The final stage of the resin impregnation comprises a drying step in order to remove the water and/or solvent(s) contained in the provided resin, from the sheet(s). The paper impregnated with resin and/or pressed at high temperature becomes transparent or translucent as the cellulose of paper and the impregnation resin have about the same refractive index. The transparency provided by the resin is particularly advantageous for use as a printed or non-printed paper layer, especially as an overlay in the latter case, for improving the performance of certain electronic devices in applications such as displays, solar cells, keyboards, or organic light emitting diode (OLED).

After the electronic device has been impregnated and encapsulated with resin it may be laminated, either as such or in an object or a product.

The lamination may be achieved using a known press under pressure and heat as disclosed in the present application. During lamination, final curing of the resin may take place. The resin is then a cross linked thermo-set material. The lamination steps may be performed to achieve the monolithic structure of the electronic device. Alternatively, it may be performed when the electronic device is integrated or embedded in an object.

It has been observed that the paper used for electronics printing such as Powercoat® XD having a smooth surface and suitable porosity enables good printability with an electronic ink as well as good impregnation with resin thereby enabling a monolithic structure.

The electronic device disclosed herein may be, but is not limited to, a near field communication (NFC) device, a radio frequency identification (RFID) device, a photovoltaic cell, an emissive display, an energy harvesting device, a loudspeaker, or a multi-layer printed circuit board (PBC).

In a particular embodiment, the electronic device is integrated into an object. In particular, the electronic device is embedded in an object which comprises materials compatible to be laminated with the resin with which the electronic device is impregnated and encapsulated. In such a case the object is produced after the electronic device has been assembled, impregnated and encapsulated with the resin.

In a particular embodiment, the electronic device is integrated into the structure of a manufactured product. In particular, the electronic device is embedded in the structure of the product during its manufacturing. In a particular embodiment, the manufactured product is of the following categories: consumer durables, interior or exterior finish, building envelope, or transport vehicles such as cars, trains, boats, planes or the like.

The electronic device is described to be “integrated” into an object or the structure of a manufactured product since the electronic device is not separable from the object or the structure of a manufactured product once integrated, and provides added electronic function while preserving the normal function of the object and without disturbing the structure of the manufactured product.

The electronic device is described to be “embedded” in said object or the structure of a manufactured product since it is strongly and seamlessly bound to the object or the structure of a manufactured product, for example, inside the object or the structure of the manufactured product.

The final form of the electronic device may be flat or curved depending on the shape of the object or the structure of a manufactured product. The electronic device is said to be of “monolithic structure” since the plurality of sheets is strongly bound to form one piece from which each sheet cannot be physically taken apart from the monolithic structure.

The invention also relates to a method for producing an electronic device, characterized according to any of the above embodiments and their combinations, comprising the steps of:

(i) providing or producing a plurality of sheets, wherein at least one of said sheets is a paper comprising a printed trace, pattern, and/or layer of an electronic ink;

(ii) optionally impregnating and encapsulating individually one or more sheets provided or produced in step (i) with a resin;

(iii) assembling said plurality of sheets in a direction perpendicular to the plane of the sheets;

(iv) when step (ii) was not carried out, impregnating and encapsulating the plurality of sheets with a resin to produce the electronic device;

(v) optionally laminating the plurality of resin impregnated and encapsulated sheets and

(vi) recovering a flat or curved monolithic structure; In a particular embodiment the method of producing the electronic device also includes a step of depositing or appending one or more electronic components which are not-printed and in particular are rigid components (examples thereof have been given herein). This step is carried out before the impregnation and encapsulation of the device or sheets.

According to this process, the step of resin impregnation and encapsulation of each sheet (or of subsets of sheets) with or without printed electronic inks, printed and/or non-printed electronic components is carried out optionally, prior to assembling the plurality of sheets in a direction perpendicular to the plane of the sheets. In one embodiment, when each sheet is impregnated and encapsulated with resin in step (ii), the assembly of the plurality of sheets may be encapsulated again in step (iv). In another embodiment, when each sheet is impregnated and encapsulated with resin in step (ii), the resin encapsulation of the assembly of the plurality of sheets in step (iv) may be skipped. In a particular embodiment the sheets, and in particular the paper sheets are individually provided as sheets pre-impregnated with resin, for the preparation of the electronic device.

In a particular embodiment, the step (i) comprises a step of printing at least one sheet with one or more traces, patterns, and/or layers of conductive ink, and/or one or more traces, patterns, and/or layers of semiconductive ink, and/or one or more traces, patterns, and/or layers of dielectric ink. Any suitable printing technology may be used such as inkjet printing, offset printing, gravure printing, screen printing, flexography, and/or electrophotography.

In a particular embodiment, the electronic device, in particular the printed electronic circuit or ink deposits, are not thicker than 200 μm, preferably not thicker than 50 μm, preferably not thicker than 20 μm. Typically, the thickness of electronic ink printing is in the order of magnitude of 10 to 20 μm for screen printing, 2 to 3 μm for flexography and around 0.3 μm for inkjet.

The method of invention preferably further comprises a step of curing or sintering the conductive and/or semiconductive and/or dielectric ink, following the ink printing step. Once the inks are applied and dried if necessary, a step of curing or sintering by thermal annealing, photonic curing, or ultraviolet (UV)-radiation annealing takes place, in order to sinter the small particles in the ink and achieve or improve electronic properties. As an example, for conductive inks, small metal particles are included in the ink that need to be, at least partly, melted or sintered in order to increase the electric conductivity significantly. Compared with commonly used plastic films used in printed electronics applications, such as PET, these papers provide a much better thermal resistance and can be sintered at much higher temperatures, for example at 200° C., compared to a maximum of 120° C. to 140° C. for PET. In particular cases, this leads to much better electric/electronic properties with the same amount of ink deposit or allows using much less ink in the deposit to achieve the same electric/electronic properties. This is a very significant advantage with some inks, especially conductive inks, made of expensive raw materials such as silver nanometric powder.

The resin impregnation and encapsulation may be carried out by applying a resin at size press on a paper machine, by placing the paper sheet to be impregnated and encapsulated in a dip pan, or by any other method in order to fill or saturate the pores of the paper sheet as well as to coat the surface of the paper sheet. The final stage of the impregnation and encapsulation step comprises a drying step to remove any water or solvent from the resin (i.e. wet resin) in the paper, and/or a step of partially curing or partially solidifying the resin.

The resin used in the process as disclosed herein impregnates and encapsulates a paper sheet or the assembly of the sheets in the electronic device, in such a way that the percentage weight change after the step of resin impregnation and encapsulation is in the range of 20 to 90%. The percentage weight change is determined by finding the difference between the weight of a paper sheet or the assembly of the sheets with or without electronic components (printed or non-printed portion) just before the step of resin impregnation (and encapsulation) and the weight of the same after the step of resin impregnation (and encapsulation).

In a particular embodiment when the electronic device is as such laminated or laminated in an object or a manufactured product, the lamination step may be carried out under a pressure in the range of 20 to 100 bars and a temperature in the range of 120 to 200° C. for a duration of 15 seconds to 90 minutes.

For example, for low pressure lamination process (LPL), a pressure in the range of 20 to 30 bars is applied at a temperature range in the range of 150 to 180° C. for a duration of 15 to 150 seconds. In a particular embodiment, the low pressure lamination process is carried out at 180° C. with an applied pressure of 20 bars for 1 minute.

For example, for high pressure lamination process (HPL), a pressure in the range of 40 to 100 bars is applied at a temperature in the range of 120 to 180° C. for a duration of 30 to 60 minutes. In a particular embodiment, the high pressure lamination process is carried out at 160° C. with an applied pressure of 60 bars for 30 minutes.

Lamination is carried out by pressing two or more resin impregnated and encapsulated sheets together by applying heat and pressure simultaneously for a given duration of time. The lamination may be carried out to produce objects in flat or non-flat form.

In a low pressure lamination process, papers typically of melamine impregnated decorative paper are pressed at pressures of about 20 to 30 bars and at about 150 to 200° C. (according to procedures such as disclosed in plastic laminate symposium, Aug. 17-20, 1998).

In a high pressure lamination process, high pressure laminate comprising several layers of resin impregnated papers are pressed at pressures exceeding 50 bars and temperatures greater than 125° C. (according to procedures such as disclosed in plastic laminate symposium, Aug. 17-20, 1998).

The invention also concerns an electronic device for use in the manufacture of an object or product. In a particular embodiment, the electronic device may be integrated into said object or manufactured product during its manufacturing by the lamination process disclosed above. The object is or is a part of the following categories: consumer durables, interior or exterior finish, building envelope, or transport vehicles such as cars, trains, boats, planes or the like.

Accordingly the monolithic structure of the electronic device may be obtained when the impregnated and encapsulated device is integrated or embedded in an object or product through a lamination process.

Particular features of the invention will be illustrated in the examples which follow and in the accompanying drawings. The features disclosed in respect of these examples also define embodiments of the invention described above and accordingly may be specified in combinations with these embodiments.

### BRIEF DESCRIPTION OF THE DRAWINGS

FIG. 1: assembly of layers and sheets in an electronic device for photovoltaic application

FIG. 2: assembly of layers and sheets in an electronic device for emissive display application

FIG. 3: assembly of layers and sheets in an electronic device for energy harvesting application

FIG. 4: assembly of layers and sheets in an electronic device for loudspeaker application

FIG. 5: multilayer printed circuit board replacement

### EXAMPLES

The inventors have provided illustration of devices encompassing Printed Electronics Circuitries on paper with improved properties accordingly overcoming shortcomings inherent to untreated paper which may remain physically fragile and tearable. These devices also solve the problem of devices built on paper that are not a self-sustainable structure, in particular when paper of low grammage is used. Accordingly it is generally considered that printed electronics circuitry on non-treated paper needs to be glued or embedded onto a support/product as a label or an inlay. Additionally, paper on its own contains 5% water, and is a poor barrier to water, grease or oxygen. Many applications are beyond the capabilities of Printed Electronics on paper in such conditions.

The inventors have provided improved solution by proposing an electronic device which involves impregnation and encapsulation of the paper sheets that it contains, including of the functionalized paper sheets after printing or depositing electronic components, with a resin. Accordingly the obtained structure although a monolith (as a result of assembly of sheets and final lamination) exhibits sufficient bending stiffness and resistance and also enables providing a barrier, in particular to moisture (water) and oxygen and optionally to grease.

The combination of resin use and laminates approach which is provided according to the invention to produce the electronic device is opening wide applications including due to its ability to provide combination of sheets (or layers) in the z-direction (perpendicular to the plane of the sheets), thereby enabling the piling up of layers of circuitries or active electronics components and their supply as a monolithic structure or laminate wherein the circuitry and more generally the electronic components are embedded. The electronic components are said to be “embedded” since the various sheets of the electronic device are strongly bound to each other and therefore may be considered to be an integral part of a monolithic or laminate structure.

At the end of the resin impregnation, encapsulation and lamination (enabling curing of the resin), the end product would be waterproof, oxygenproof and also greaseproof in a very integrated manner.

Printing of an electronic component or circuit on paper substrate can be carried out using a flat screen, rotary screen, flexographic, or inkjet printer. The electronic component or circuit printed using commercial silver-based inks (or other inks comprising metal particles) may then be sintered by high temperature IR (150-180° C.), thermal annealing, UV-curing or photonic curing. Printed dielectric or insulating (non-conductive) inks may be heat or UV-cured for circuitry insulation and cross-over bridges.

In order to integrate the electronic device into a product such as a paper (e.g. for the manufacture of functionalized end products such as functionalized wallpaper, especially obtained by lamination with the electronic device) a known roll-to-roll manufacturing process may be used.

According to the invention, the different sheets of the electronic device may be individually (or as subsets of sheets) impregnated with the resin. In such a case the type or composition of the resin may be identical or different for each sheet (or subset of sheets). In another embodiment, the assembly of sheets is impregnated with resin and encapsulated. In a further embodiment the electronic device is obtained after combining steps of resin impregnation of the individual sheets (or subsets of sheets) and impregnation and encapsulation of the assembly of sheets prior to their lamination.

In the following Examples the papers used to print or to deposit the functional electronic traces, patterns and/or layers are papers produced according to WO 2015/059157 or accordingly are papers commercialized under the trademark Powercoat® XD.

### Example 1: Photovoltaic Application

Using paper in a photovoltaic application would be considered very challenging for various reasons:
Photovoltaic (PV) materials, in particular the organic printable ones, tend to be very sensitive to oxygen and water. Accordingly, excellent barrier is required.
Most applications of PV are outdoor which may be regarded as not compatible with paper use due to its sensitivity to moisture.

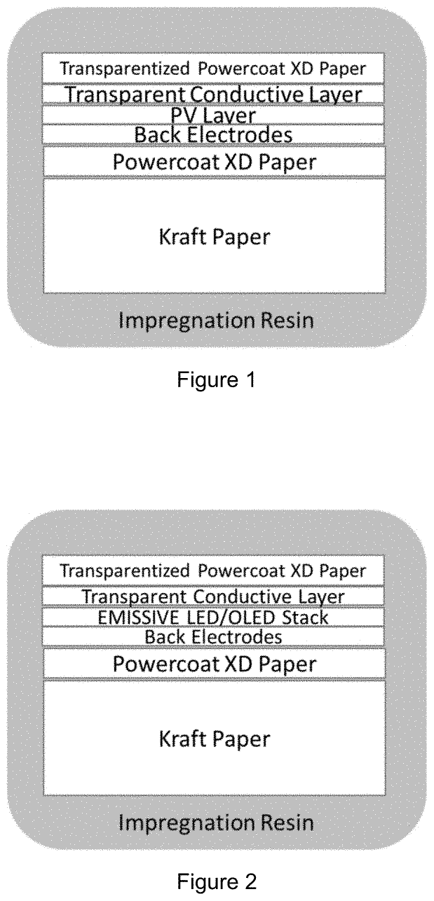

It was however possible to conceive a suitable photovoltaic device (FIG. 1) using paper as a substrate to embed electrodes, PV layer and back printed electrode in a sandwich impregnated and encapsulated with resin. The arranged layers i.e., transparent conductive layer, PV layer, printed layer forming back electrode were provided on a sheet of support paper which was applied on a Kraft paper sheet. A transparent or translucent sheet obtained after resin impregnation of a Powercoat XD paper may also be added on top of the functional sheet obtained after deposit or printing of the electronic components. Alternatively, the transparent conductive layer may be deposited or printed on said transparentized Powercoat XD paper rather than overlapping with the other electronic components. A Kraft paper sheet is used as a balancing layer at the bottom of the device and it accordingly stabilizes the device. The process of producing a solar cell according to the invention is as follows:

1/ Printing the different layers on Powercoat XD paper with a screen printing machine, in an inert gas atmosphere:
First layer is an electrode printed with Orgacon silver ink SI-P1000X from Agfa, 3 μm in thickness.
Second layer is the PV layer printed with Lisicon® PV-D series/Lisicon® PV-A series blend as an active layer (200 nm) from Merk
Third layer is a second electrode printed with Pedot/PSS EL-P5015 from Agfa, 400 nm in thickness

2/ Impregnating the paper in step 1 with a solvent-base MF resin

3/ Impregnating a Powercoat XD paper with a solvent-based MF resin to obtain a transparent paper

4/ Pressing the different layers of paper, together with a Phenolic pre-impregnated kraft paper in a HPL process (160° C., 60 bars, 30 minutes).

The solar cell made by this method showed a Power Conversion Efficiency of 5% for 6 month at 23° C. and 50% humidity.

### Example 2: Emissive Display Application

Using paper in a display application would be considered very challenging for various reasons:
Display material, in particular the organic printable ones, tend to be very sensitive to water and oxygen. Accordingly, excellent barrier is required.
Most applications of displays are mobile, handheld and require rugged and robust solutions which may be regarded as incompatible with paper solution due to its fragility.

Using various sheets of specialty paper it was possible to conceive a display (FIG. 2) using paper as a substrate to embed top transparent electrodes, a display stack (that may be emissive LED or OLED stack) and back printed electrode in a sandwich impregnated and encapsulated with resin. The arranged layers i.e., were provided on a sheet of support paper which was applied on a Kraft paper sheet. Alternatively, the transparent conductive layer may be deposited or printed on the transparentized Powercoat XD paper rather than overlapping with the other electronic components. The process of producing a light emitting diode stack according to the invention is as follows:

1/ Printing the different layers on Powercoat XD paper with a screen printing machine, in an inert gas atmosphere:
First layer is an electrode printed with Orgacon silver ink SI-P1000X from Agfa, 3 μm in thickness.
Second layer is the OLED layer printed with Livilux® OLED series as an active layer (200 nm) from Merk
Third layer is a second electrode printed with Pedot/PSS EL-P5015 from Agfa, 400 nm in thickness

2/ Impregnating the previous paper with a solvent-base MF resin

3/ Impregnating a Powercoat XD paper with a solvent-based MF resin to obtain a transparent paper

4/ Pressing the different layers of paper, together with a Phenolic pre-impregnated kraft paper in a HPL process (160° C., 60 bars, 30 minutes).

OLED constructed by this process showed a working yield of 90% for 2 month at 23° C. and 50% humidity.

### Example 3: Energy Harvesting Application

Using paper in an energy harvesting application would be considered very challenging for various reasons:
Piezo materials, in particular the organic printable ones, tend to be very sensitive to water. Accordingly, excellent barrier is required.
Most applications of energy harvesting is flooring or outdoor which may be regarded as not compatible with paper use due to its sensitivity to moisture, its rugged requirement, scratch resistance, etc. . . .

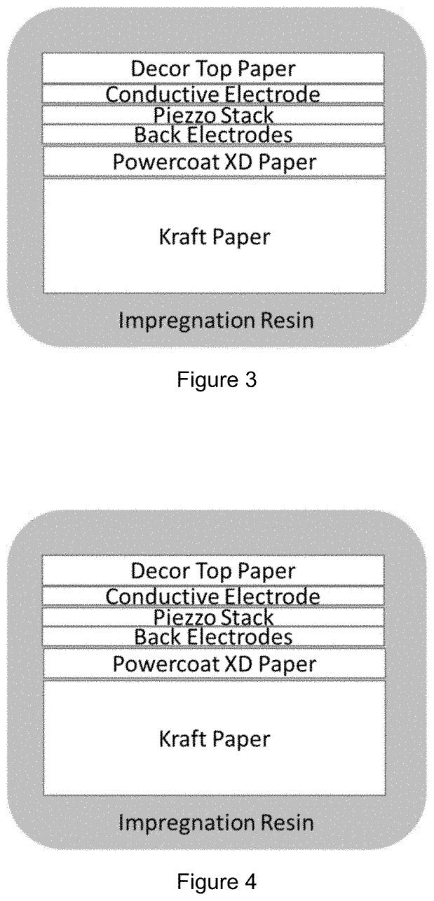

Using various sheets of specialty paper it was possible to conceive a display (FIG. 3) using paper as a substrate to embed top décor paper, printed electrodes, piezo layer and back printed electrode in a sandwich impregnated and encapsulated with resin. The arranged layers i.e., were provided on a sheet of support paper which was applied on a Kraft paper sheet. On the support sheet rendered functional with the electronic components, a transparent or translucent sheet obtained after resin impregnation of a Powercoat XD paper may be added. Alternatively, the conductive electrode may be deposited or printed as a layer on the décor paper rather than overlapping with the other electronic components. The process of producing an energy harvesting device according to the invention is as follows:

1/ Printing the different layers on Powercoat XD paper with a screen printing machine:
First layer is an electrode printed with Orgacon silver ink SI-P1000X from Agfa, 3 μm in thickness.
Second layer is the Piezzo layer printed with Piezotech® FC25 ink P from Piezzotech ARKEMA, 4 μm in thickness
Third layer is printed with Orgacon silver ink SI-P1000X from Agfa, 3 μm in thickness.

2/ Poling the devices under 200 v (5 cycles).

3/ Impregnating the previous paper with an aqueous-base MF resin

4/ Impregnating a decor paper with an aqueous-based MF resin

5/ Pressing the different layers of paper, together with Phenolic pre-impregnated kraft paper with an HPL process (160° C., 60 bars, 30 minutes).

When a pressure of 2 bars is applied to the system, a current of is generated from the device.

### Example 4: Loudspeaker Application

The structure of the loudspeaker is exactly the same as the energy harvesting device in Example 3. In case of an energy harvesting device, vibrations as an energy source generate electricity, whereas in case of a loudspeaker, electricity generates vibrations. The process of producing a loudspeaker according to the invention is as follows:

1/ Printing the different layers on Powercoat XD paper with a screen printing machine:
First layer is an electrode printed with Orgacon silver ink SI-P1000X from Agfa, 3 μm in thickness.
Second layer is the Piezzo layer printed with Piezotech® FC25 ink P from Piezzotech ARKEMA, 4 μm in thickness
Third layer is printed with Orgacon silver ink SI-P1000X from Agfa, 3 μm in thickness.

2/ poling the devices under 200 v

3/ Impregnating the previous paper with an aqueous-base MF resin

4/ Impregnating a decor paper with an aqueous-based MF resin

5/ Press the different layers of papers, including also Phenolic pre-impregnated kraft paper with an HPL process (160° C., 60 bars, 30 minutes).

When an alternative tension of 24 V is applied to the loudspeaker, sound is generated by the device.

### Example 5: Multi-Layer Printed Circuit Board (PCB) Replacement

Printed circuit board (PCB) is usually made of Epoxy Resin and FiberGlass. In the art, it was known to perform resin impregnation and lamination of layers of pre-impregnated fabrics or Kraft paper with copper metal foils to enable a succession of conductive circuitries. In such devices, discrete components were however soldered on top/bottom of the PCB. Air was used to cool the electronics down (thermal sink).

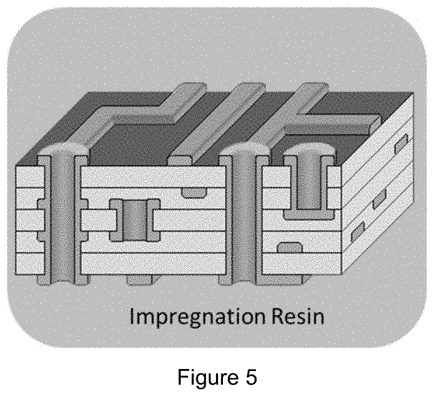

Printed Electronics Circuitry on Paper (FIG. 5) may be complex to handle, in particular when connecting to the external world is at stake. The solution provided by the invention enables Printed Electronics Papers assembly together in the z-direction, and the subsequent impregnation step with resin enables providing a rigid structure that can be easily connected.

In this device, resin encapsulates sensitive components or chemicals to protect them from oxygen and water or moisture. It also has a structural role to hold connector and reduce fragility in a protective monolithic structure wherein the circuitry and components are embedded.

Additionally key issue is the assembly mode that enables creating vias that are well aligned to enable circuitry continuity between the layers.

The process of producing a multi-layer printed circuit board (PCB) replacement is as follows:

1/ Printing the first circuitry on Powercoat XD paper with a screen printing machine:
First circuitry layer printed with an Orgacon silver ink SI-P1000X from Agfa, 3 μm in thickness.
holes drilled with a laser
Via printed with an Orgacon silver ink SI-P1000X from Agfa,

2/ Printing the second circuitry on Powercoat XD paper with a screen printing machine:
First circuitry layer printed with an Orgacon silver ink SI-P1000X from Agfa, 3 μm in thickness.
holes drilled with a laser (3 mm in diameter)
Via printed with an Orgacon silver ink SI-P1000X from Agfa,

3/ Impregnating the previous papers with an aqueous base MF resin

4/ Aligning the 2 layers with the via holes

5/ Pressing the different layers of papers, together with Phenolic pre-impregnated kraft paper with an LPL process (180° C., 20 bars, 1 minute).

By contrast to systems provided in the art, the paper-in-resin electronics technology provides a device wherein each layer can present its circuitry and its electronics functions. In addition in the assembly of the invention, when electronics functions require barrier protection or thermal sinking, the impregnating resin brings this protection and performs the role of thermal vector.

### Example 6: Examples of Papers_Suitable for Printing Electronic Inks and being Impregnated with a Resin

TABLE 1
_Powercoat ®XD papers having basis weight (grammage) of 125 g and 200 g.
POWERCOAT XD Paper

| Characteristics | Apparatus | Standards | | | 125 g | 200 g |
|---|---|---|---|---|---|---|
| Basis | L2200 | NF EN ISO 536- RNE | | | 129 | 202 |
| Weight g/m² | Balance | PC.110- RNE PC.111 | | | | |
| Thickness μm | MI20 | NF EN ISO 20534- PC.90 | | | 128 | 204 |
| | | ISO 534- PC.91/PC.101 | | | | |
| Bulk cm³/g | | | | | 0.99 | 1.01 |
| Smoothness | Bekk [s] | | | | 136 | 80 |
| | Profilometer | | | | 1500 | 2000 |
| | Ra [nm] | | | | | |
| Porosity | Bendtsen L&W | NF Q 03-076-COFRAC PC.390 | | | 2 | 35 |
| ml/min | | ISO 5636/3-COFRAC PC.391 | | | | |
| Tear | Tear tester | NF EN 21974- RNE PC.60 | | MD | 576 | 871 |
| mN | 60-220 | | | CD | 604 | 932 |
| Tear Index | | | | MD | | 4 |
| mN · m²/g | | | | CD | 5 | 5 |
| Tensile | Tensile tester | NF EN ISO 1924- | Force | MD | 134 | 183 |
| | MTC-100 | COFRAC PC.20- | N | CD | 70 | 93 |
| | | COFRACPC.21 | Elongation | MD | 3.23 | 2.94 |
| | | | mm | CD | 7.58 | 5.90 |

| Stiffness Nmm | Stiffness | ISO 2493 | MD | 1.50 | 4.04 |
|---|---|---|---|---|---|
| | tester Frank | | CD | 0.96 | 2.37 |
| | 42067 | | | | |
| Burst kPa | Bursting tester | NF Q 03-053- RNE PC0.40 | | 386 | 489 |
| Burst Index | EC05 | ISO 2758-RNE PCO.41 | | 3 | 2 |
| kPa · m²/g | | | | | |
| Brightness | ColorTouch CTHA 2045 | NF Q 03-039- RNE PC.200 | | 82.6 | 82.4 |
| | | ISO 2470- RNE PC.201 | | | |
| Yellowing after | ColorTouch CTHA 2045 | Internal method | 5 minutes at | 2.8 | 2.6 |
| curing (ΔE) | | | 180° C. | | |
| Moisture | Oven | NF EN 20 287-PC.40 | Wet weight | 8.11 | 12.64 |
| Content % | Gallenkamp Kern Balance | ISO 287-PC.41 | Dry weight | 7.72 | 12.12 |
| | | | Moisture content | 4.81 | 4.11 |

| | | | | |
|---|---|---|---|---|
| Shrinkage % | Unrestrained at 200° C./5 min | MD | −0.36 | −0.35 |
| | | CD | −0.71 | −0.70 |
| | Reconditioned at 23° C./50% RH | MD | −0.10 | −0.07 |
| | | CD | −0.19 | −0.14 |

TABLE 2
Powercoat ®XD papers having basis weight (grammage) of 84 g.
POWERCOAT Paper

| Charateristics | Apparatus | Standards | | | PWC CHAM |
|---|---|---|---|---|---|
| Basis Weight g/m² | Sartorius L2200 | NF EN ISO 536- RNE | | | 84.0 |
| | Balance | PC.110- RHE PC.111 | | | |
| Thickness μm | MI20 | NF EK ISO 23534- PC.90 | | | 77 |
| | | ISO 534- PC.91/PC.101 | | | |
| Bulk cm³/g | | | | | 0.92 |
| Smoothness | Bekk (s) | | | Recto | 284 |
| | | | | Verso | 263 |
| Porosity ml/min | Bendtsen L&W | NF Q 03-076-COFRAC PC.390 | | | 3.4 |
| | | ISO 563S/3-CDFRAC PC.391 | | | |
| Tear mN | Tear tester | NF EN 21974-RNE PC.60 | | MB | 447 |
| | 63-320 | | | CD | 510 |
| Tear Index | | | | MB | 5 |
| mN · m²/g | | | | CD | 6 |
| Tensile | Tensile tester | NF EN ISO 1924- | Force N | MB | 34.18 |
| | MTC-130 | COFRAC PC.20- | | CD | 45.34 |
| | | COFRAC PC.21 | Elongation mm | MU | 2.73 |
| | | | | CD | 10.48 |

| Modulus Gpa | DMA | 50° C. | MU | |
|---|---|---|---|---|
| | | 125° C. | MB | |
| | | 200° C. | MB | |
| Stiffness Nmm | Stiffness tester | ISO 2493 | MU | |
| | Frank 42867 | | CD | |
| Burst kPa | Bursting tester | NF Q 03-053- RNE PC0.40 | | 218 |
| Burst Index | EC05 | ISO 2758-RNE PCO.41 | | 2.6 |
| kPa · m²/g | | | | |
| Brightness | Color Touch | NF Q 03-039- RNE PC.200 | | 81.5 |
| | CTHA 2045 | ISO 2470- RNE PC.201 | | |
| Yellowing after | Color Touch | Internal method | 5 minutes at 180° C. | 2.1 |
| curing (□E) | CTHA 2045 | | 5 minutes at 200° C. | 5.2 |

| | | | |
|---|---|---|---|
| Shrinkage % | Unrestrained at 200° C./5 min | MB | −0.39 |
| | | CD | −0.65 |
| | Reconditioned at 23° C./50% RH | MB | −8.84 |
| | | CD | −3.15 |

| | | |
|---|---|---|
| Dieiectric Permittivity | Internal method | at 988 MHz |
| dielectric loss (tan □) | | at 2.45 GHz |

| | |
|---|---|
| Resistance [ohm] of a 10 cm line and 0.5 mm in width | 43.4 |

1.-22. (canceled)

23. An electronic device comprising a plurality of sheets assembled in a direction perpendicular to the plane of the sheets, wherein at least one of said sheets is a sheet of paper comprising a printed trace, pattern, and/or layer of an electronic ink, and wherein the assembly of plurality of sheets is impregnated and encapsulated with a resin in a form of a flat or curved monolithic structure.

24. The electronic device according to claim 23, wherein at least two of the plurality of sheets are paper sheets comprising printed traces, patterns, and/or layers of a conductive ink.

25. The electronic device according to claim 23, wherein all paper sheets have a Bendtsen porosity greater than 1 ml/min.

26. The electronic device according to claim 23, wherein the at least one paper sheet comprises a printed trace, pattern, and/or layer of an electronic ink having a Bekk smoothness greater than 50 s.

27. The electronic device according to claim 23, wherein the at least one paper sheet comprises:
a printed trace or layer of a semiconductive ink and/or,
a printed trace or layer of a dielectric ink.

28. The electronic device according to claim 27, wherein the at least one paper sheet comprises one or more traces, patterns, and/or layers of a conductive ink, and/or one or more traces, patterns, and/or layers of a semiconductive ink, and/or one or more traces, patterns, and/or layers of a dielectric ink.

29. The electronic device according to claim 23, wherein the at least one paper sheet comprises one or more types of conductive inks, and/or one or more types of semiconductive inks, and/or one or more types of dielectric inks.

30. The electronic device according to claim 23, wherein each sheet in the plurality of sheets is a sheet of paper.

31. The electronic device according to claim 23, wherein each of the at least one paper sheet is a coated paper including a coating comprising a binder and pigments.

32. The electronic device according to claim 31, wherein each coated paper has at least one of the following features:
a. It contains a coating composition comprising a binder with a glass transition temperature lower than 20° C.;
b. It comprises 0.05 to 15 parts dry weight of viscosifying agent;
c. It has a Bekk smoothness greater than 50 s.

33. The electronic device according to claim 32, wherein the coating of each coated paper comprises a binder selected from a group consisting of acrylic polymer, polyurethane, polymethyl methacrylate, styrene butadiene, vinyl acetate, polyamide, nitrocellulose or any other cellulose, polyvinyl alcohol, starch and a mixture thereof.

34. The electronic device according to claim 23, wherein:
a. the conductive ink comprises metallic microparticles or nanoparticles and/or conducting polymers and/or
b. the semiconductive ink comprises semiconducting microparticles or nanoparticles and/or semiconducting polymers and/or
c. the dielectric ink comprises insulating polymers.

35. The electronic device according to claim 23, wherein the at least one sheet comprises at least one electronic component.

36. The electronic device according to claim 23, wherein the resin is selected from a group consisting of melamine formaldehyde (MF) resin, urea formaldehyde (UF) resin, urea-melamine-formaldehyde (UMF) resin, acrylic resin, phenolic resin, polyester resin, epoxy resin, and any mixtures thereof.

37. The electronic device according to claim 23, which is a near field communication (NFC) device, a radio frequency identification (RFID) device, a Bluetooth device, a Wi-Fi device or other ultra-high frequency device, a photovoltaic cell, an emissive display, an energy harvesting device, a loudspeaker, selective electromagnetic shielding or a multi-layer printed circuit board (PBC) replacement.

38. An object comprising the electronic device according to claim 23, wherein the electronic device is integrated into the object which comprises at least one electronic device integrated into its structure.

39. A method for producing an electronic device, comprising the steps of:
(i) providing or producing a plurality of sheets, wherein at least one of said sheets is paper comprising at least one of a printed trace, pattern, and layer of an electronic ink;
(ii) impregnating and encapsulating at least one of the sheets with resin and assembling the plurality of sheets in a direction perpendicular to a plane of the sheets; or
(iii) assembling the plurality of sheets in a direction perpendicular to a plane of the sheets and impregnating and encapsulating said plurality of sheets with resin;
(iv) laminating the plurality of sheets and,
(v) forming a flat or curved monolithic structure from the plurality of sheets.

40. The method of claim 39, wherein at least one of the sheets includes a deposited or appended non-printed electronic component.

41. The method according to claim 39, further comprising:
a. printing at least one sheet of the plurality of sheets with one or more traces, patterns, and/or layers of one or more conductive inks, and/or one or more traces, patterns, and/or layers of one or more semiconductive inks, and/or one or more traces, patterns, and/or layers of one or more dielectric inks by inkjet printing, offset printing, gravure printing, screen printing, flexography, and/or electrophotography and/or,
b. curing or sintering the electronic ink.

42. The method according to claim 39, wherein the resin is selected from a group consisting of melamine formaldehyde (MF) resin, urea formaldehyde (UF) resin, urea-melamine-formaldehyde (UMF) resin, acrylic resin, phenolic resin, polyester resin, epoxy resin and any mixtures thereof.

43. The method according to claim 39, wherein step (iv) is carried out under a pressure in the range of 20 to 100 bars and a temperature in the range of 120 to 200° C. for a duration of 15 seconds to 90 minutes.

44. The method according to claim 39, wherein the electronic device comprises a plurality of sheets assembled in a direction perpendicular to the plane of the sheets, wherein at least one of said sheets is a sheet of paper comprising a printed trace, pattern, and/or layer of an electronic ink, and wherein the assembly of plurality of sheets is impregnated and encapsulated with a resin in a form of a flat or curved monolithic structure.
